(19) United States
(12) Patent Application Publication
(10) Pub. No.: US 2013/0213455 A1
(43) Pub. Date: Aug. 22, 2013

(54) HYBRID SOLAR COLLECTOR

(71) Applicant: David Matalon, Brooklyn, NY (US)

(72) Inventor: David Matalon, Brooklyn, NY (US)

(73) Assignee: MATALON ENERGY, LLC, New York, NY (US)

(21) Appl. No.: 13/401,898

(22) Filed: Feb. 22, 2012

(51) Int. Cl. H01L 31/058; F24J 2/38; F24J 2/12; F24J 2/40; F24J 2/04

(52) U.S. Cl. 136/248; 126/595; 126/634; 126/694; 126/585

(57) ABSTRACT

A hybrid solar collector is disclosed having a passive solar collector unit and active photovoltaic panels. The inclination angle of the photovoltaic panels is optimized by linking the panels to the passive unit and its associated tracking controls.

### BACKGROUND OF THE INVENTION

1. Field of the Invention

The invention relates to solar collectors, including an apparatus having both active and passive solar collector elements, and a tracking system for controlling both elements simultaneously. Improvements in a solar collector tracking control system are also described and enabled, including an error condition detector, and provision for defocusing a collector surface of the apparatus when an error condition is detected.

2. Description of the Related Art

A parabolic solar collector apparatus is disclosed in U.S. Pat. No. 8,069,849, by the inventor herein, which is incorporated by reference in its entirety. The aforesaid patent discloses a collector having a base made of relatively light weight foam, which forms a support for a reflective collector surface. The collector surface focuses solar radiation on a receiver element located in a focal area of the focusing reflector. The advantages of using the foam base include the ability to calibrate the focusing reflector surface at low cost using relatively inexpensive processes, such as “hot wire” cutting with CNC control. Due in part to good calibration obtained with these fabrication methods, highly energy efficient operation is achieved.

The aforesaid patent also discloses a tracking system which maximizes the energy efficiency of the apparatus. The collector, which may be for example trough-shaped or dish-shaped, is positioned generally on a North-South axis, so that the curve of the focusing surface faces toward the sun and pivots from East to West to follow the apparent movement of the sun across the sky during the day.

The tracking system described in the aforesaid patent is provided to adjust the inclination angle of the collector surface to maximize the amount of solar radiation incident on the collector surface throughout the day. The tracking system comprises heat sensors disposed about a centrally located receiver. A control unit operatively connected to a motor for adjusting the angle of the collector and to the heat sensors is adapted to shift the inclination angle of the collector surface in the direction of the heat sensor registering the colder temperature. One or more additional heat sensors may be located below the receiver (or otherwise between the two heat sensors described above) to act as a “fine tune,” preventing the inclination angle from adjusting when the temperature measured at the middle sensor is higher than the temperature measured on either side of the receiver.

The tracking control system has proven so effective that it is now desired to improve the performance of an active solar collector (such as a photovoltaic panel), using the same system. The inventor herein has thus envisioned a device producing both useful heat and electricity.

The inventor has further found that problems may arise with the functioning of the tracking system requiring one or more units to be taken off-line. Pump failure or other mechanical failure for example may cause the heat transfer fluid at the outlet of the receiver to reach an unsafe temperature. This is generally a sign that one element or another has failed. A failed unit needs to be removed from service to prevent potential damage to the apparatus. If several units are arranged in series, such that the heat transfer fluid output from one collector becomes the input for another, it becomes particularly important to take a malfunctioning unit out of operation. Thus, a further object of the invention is to provide a means for detecting an error condition and a method for managing a detected error condition in a solar collector apparatus.

These and other objects of the invention are achieved according to the invention as follows.

### SUMMARY OF THE INVENTION

The inventors have now realized a hybrid solar collector having passive and active elements. According to the invention, the tracking control system provided with the passive solar collector is simultaneously used to control the inclination angle of the passive collector surface and the collector surface of an associated active unit.

In one aspect, the invention is a combination of a passive solar collector and an active solar collector, comprising: (1) a passive solar collector unit having a reflective collector surface disposed at an inclination angle, (2) an active solar collector unit having an active collector surface disposed at the same inclination angle and moving in unison with the reflective collector surface; and (3) a tracking control system simultaneously controlling the inclination angle of the reflective collector surface of the passive solar collector and the active collector surface of the active solar collector.

In embodiments, the apparatus comprises a passive solar collector unit having a focusing collector surface in the shape of a parabolic trough, and an associated receiver element carrying a heat transfer fluid in a focal area of the collector. A motor is adapted to adjust the inclination angle of the collector surface responsive to signals from a control unit, and a photovoltaic panel is attached to the passive unit along the top edge of collector surface, so that the surface of the photovoltaic panel moves with the focusing reflector surface. A photovoltaic panel surface is usually flat and the optimal incident angle for solar radiation is normal to the surface of the panel. In this particular case, the focusing collector and active panel have the same inclination angle when the panel surface is arranged so that a line normal to the surface of the panel is parallel to the axis of symmetry of the parabolic focusing surface.

The passive unit produces heat, and the active photovoltaic panels produce electricity, which are extracted respectively and independently of each other using means known in the art.

In another aspect, the invention is a tracking control system for a solar collector, comprising: (1) a focusing collector surface; (2) an associated receiver carrying heat transfer fluid in a focal area of the collector surface; (3) a plurality of heat sensors positioned proximate the receiver; (4) a fluid temperature sensor adapted to measure the temperature of heat transfer fluid exiting the collector; (5) a motor operatively connected to the collector surface for adjusting the inclination angle of the collector surface; (6) a comparator comparing the fluid temperature of heat transfer fluid exiting the passive unit with a predetermined error condition value; and (7) a control unit operatively connected to the comparator, the plurality of heat sensors and the motor, and adapted to defocus the collector surface by moving the inclination angle to the East by a predetermined amount when the heat transfer fluid exiting the unit is above the predetermined error condition value.

A corresponding method for detecting and managing an error condition in the solar collector described above comprises the steps of: (a) obtaining a comparison of measurements from the plurality of heat sensors; (b) adjusting an inclination angle of the collector surface responsive to the comparison obtained in step (a) to focus solar radiation incident on the collector surface onto the receiver; (c) measuring the temperature of heat transfer fluid exiting the apparatus; (d) obtaining a comparison of the measurement obtained in step (c) with a predetermined error condition value; (e) adjusting the inclination angle at least 10 degrees to the East when the measurement obtained in step (c) is greater than the predetermined error condition value (indicating an error condition).

In embodiments, the method may return the apparatus to normal operation by: (f) performing steps (a) and (b) when the measurement obtained in step (c) is less than a predetermined set point less than the predetermined error condition value.

### BRIEF DESCRIPTION OF THE FIGURES

FIG. 1 is a schematic view of a hybrid solar collector according to the invention, having photovoltaic panels arranged along the sides of a trough-shaped parabolic passive solar collector.

FIG. 2A and FIG. 2B schematically illustrate the effect of defocusing a reflector, so that solar radiation incident on the reflector is not focused on the receiver.

FIG. 3 depicts features of an “open” system, wherein the parabolic reflector surface is not provided with a cover.

FIG. 4 depicts a feature of another embodiment of an “open” system, wherein a relatively large reflector surface is obtained by using sections of structural foam base material.

FIG. 5 depicts a “closed” system, wherein photovoltaic panels are provided on a parabolic collector having a cover.

### DETAILED DESCRIPTION OF THE PREFERRED EMBODIMENTS

The term “passive solar collector” refers to a unit having a reflective collector surface that reflects solar radiation from the collector surface onto a receiver element carrying a heat transfer fluid. Thus, a passive solar collector collects heat in a heat transfer fluid. An “active solar collector” refers to a unit which generates electric current from solar radiation incident on an active collector surface, typically a photovoltaic panel.

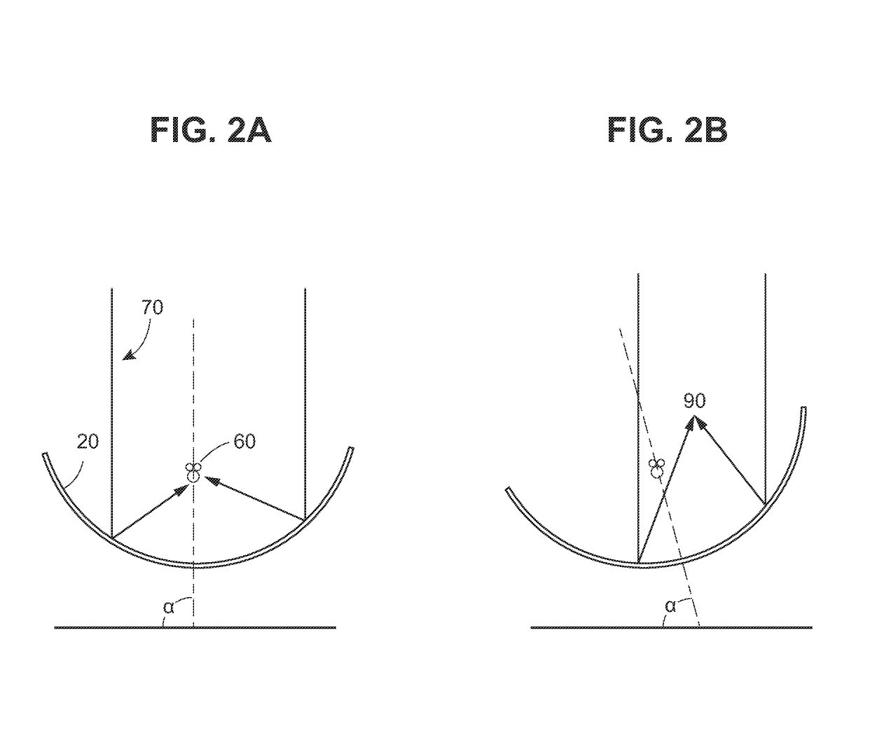

The collector surface of either type of solar collector must be disposed facing the sun. The “inclination angle” a is selected so as to maximize the amount of solar radiation incident in a perpendicular direction on the collector surface. Thus, “inclination angle” means, with respect to any flat collector surface, the angle formed between the horizontal (sometimes referred to herein as the “earth”) and a line perpendicular to the collector surface in the direction of the sun (“flat” in this context, refers to the macroscopic dimensions of the collector, such that irregularities, shapes and patterns on a flat surface are ignored for the purpose of determining the inclination angle). In the case of a reflective collector surface having an axis of symmetry, such as a dish or a parabolic trough, the “inclination angle” is the angle formed between the horizontal and the axis of symmetry of the collector surface in the direction of the sun. This axis is shown by the dotted line in FIG. 2A and FIG. 2B, which forms an inclination angle a with the horizontal. In some cases, a collector surface is formed of multiple sections, and the axis of symmetry is taken with respect to the surface formed from the multiple sections taken together. If the collector surface is curved but for some reason lacks an axis of symmetry, the inclination angle is the angle formed between the horizontal and a line perpendicular to a straight line connecting the two outermost edges of the surface. “Inclination angle” is a common-sense concept and its interpretation will be apparent in most instances to one of ordinary skill in the art, from the technical context and given these guidelines.

In general, a solar collector according to the invention is positioned on a North-South axis, so that the inclination angle varies from East to West during the day, following the apparent position of the sun. As would be understood to the person of ordinary skill, positioning of the reflector surface with respect to due North will vary depending on the season, the geographical location of the reflector and other local factors. North-South is thus a very general designation, including within its scope Northeast-Southwest and Northwest-Southeast

A “focusing surface” simply means that solar radiation incident on the collector surface is concentrated on the receiver when the collector surface achieves a desired inclination angle. Preferably, a collector surface has the shape of a parabolic dish or parabolic trough so that the focal area is well defined by the focal point of the parabola, as described in the aforesaid U.S. Pat. No. 8,069,849. However, as would be understood by the person of ordinary skill in the art, only a portion of the reflector surface need be parabolic, sufficient to focus solar radiation on the receiver element, for the collector to be referred to as “parabolic.” In some instances a focusing surface may have limited focusing ability, yet it may serve to concentrate solar radiation on the receiver, and for the purposes of this disclosure, that would also be a focusing collector surface. The “focal area” of a collector surface is not on the surface, but that area where radiation reflected from the surface is concentrated.

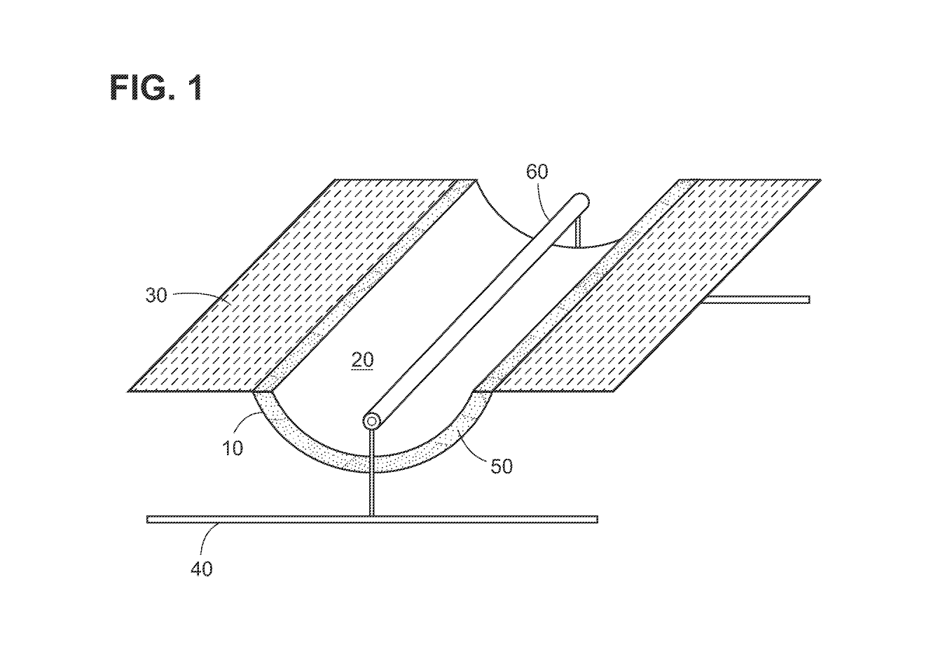

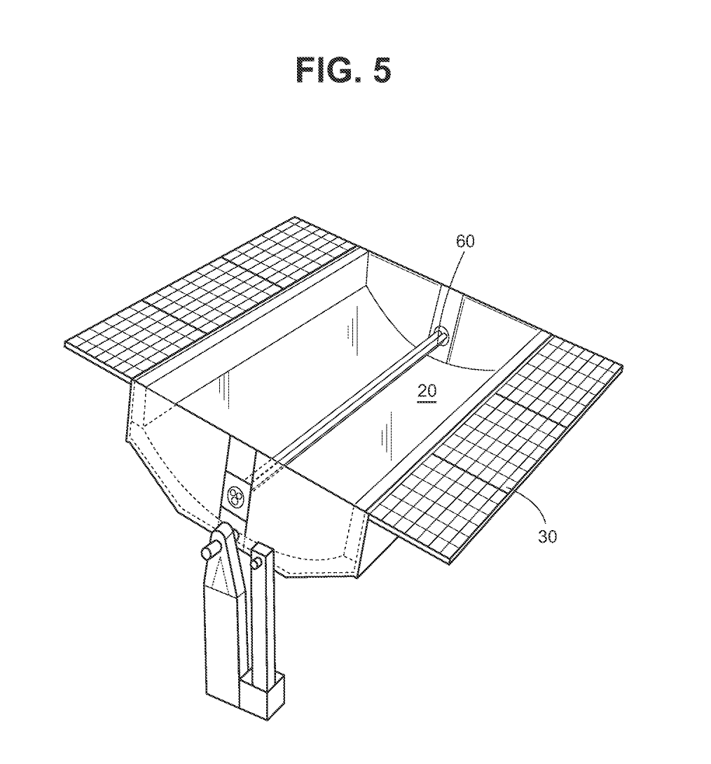

In FIG. 1, reflector surface 20 is in the form of a parabolic trough on a foam support 50 situated on a rigid support 10. A receiver 60 carrying heat transfer fluid is positioned in the focal area of the parabolic trough, so that sunlight incident on surface 20 is focused on receiver 60. The system may be provided without a cover, as shown in FIG. 1, which is referred to as an “open system,” or with a cover, as shown in FIG. 5 The preferred foam support is made from expanded polystyrene (EPS), having a density in a range of about 0.9 lb/ft³ to about 2.2 lb/ft³, which is easily cut with CNC techniques.

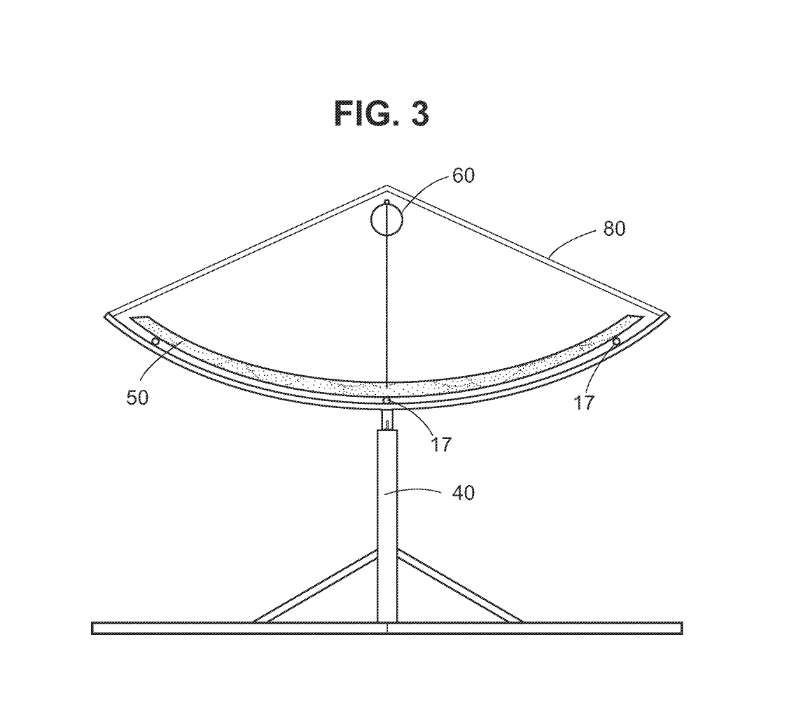

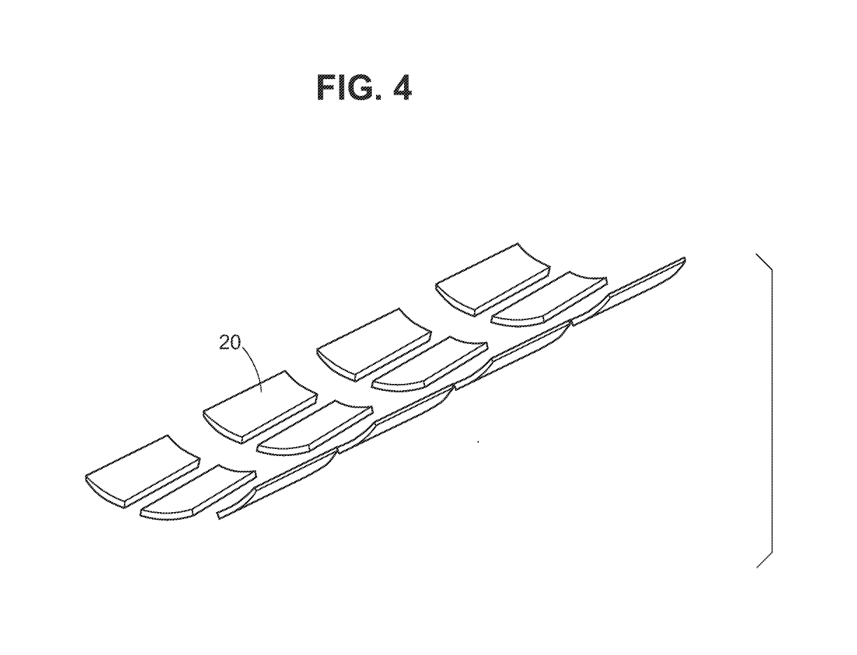

FIG. 3 schematically depicts frame elements 80 and 40 which may be used with an open system, to mount a receiver and provide integrity to the foam support 50. Generally suitable for climates with little snow or rain, the open system dispenses with a cover in favor of an evacuated tube or (less efficiently) an anti-reflective coating over the central conduit for the heat transfer fluid. Shown from the end view in FIG. 3., frame element 80 is merely a cross bar, typically no more than 1 inch wide so that it does not make significant shade on the collector surface. An advantage of dispensing with the cover is that a wider reflector surface can be formed. In embodiments, using the structural foam fabrication techniques described in the aforesaid U.S. Pat. No. 8,069,849, a large collector may be assembled from a plurality of collector surfaces 20, as shown in FIG. 4. If an open system is desired, where the curved reflective surface 20 is open to the elements, it is generally necessary to provide a coating over the foam after adhering the reflective surface, to prevent deterioration from exposure to the elements. Thus, after a sheet metal or the like reflective surface is applied on the front side, aluminum-tin sheeting having a thickness of about 0.02 inches to about 0.03 inches, or a fiberglass cloth, is suitable to line the back side of the foam support 50 to provide protection from the elements. Alternatively, a sprayable coating which is non-reactive with the preferred expanded polystyrene foam may be used. As shown in FIG. 3, there is no enclosure in which to place the curved foam support 50 in an open system. Therefore, attachment rods 17 are provided along the length of the foam support 50, which permit the surface to be mounted on end units, or with adjacent reflective surfaces so that alignment and calibration can be maintained. Attachment rods 17 may be constructed of, for example, 1 inch square metal tubes, which can be configured to align the foam support 50.

Active panels 30 are shown in FIG. 1 extending from the side edges of a parabolic trough. Panels may also extend from the ends of the parabolic trough at the same inclination angle. A rigid cradle according to U.S. Pat. No. 8,069,849 may be provided with a similar attachment of active panels as shown in FIG. 5. The type of panel is not particularly limited according to the invention. Without limitation, and for example only, Sharp USA makes a monocrystalline photovoltaic solar panel Model No. NUQ245W2 with a 250 W maximum output which can be used with the invention substantially as-is. Panels are provided with an appropriate converter to convert the current output from the panel to an output current suitable for driving one or more devices on site, for transmission, or for storing the energy in storage units (batteries). These details would be known to those of ordinary skill in the art.

Many configurations for attaching the photovoltaic panel(s) to the passive unit are possible. For example; the panels may be welded on supports positioned along the side edge of a generally trough-shaped reflector for example, or on either end of a passive unit, flush with the lip of the reflector surface. The important aspect of the attachment is that the inclination angle for the passive collector and the active collector should be the same, so that the control system for controlling the inclination angle of the passive collector unit can be used to control the inclination angle of both the active and the passive collectors.

A tracking control system identical to that disclosed in U.S. Pat. No. 8,069,849 may be used for controlling the inclination angle of the reflective collector surface and the active collector surface. In preferred embodiments, the receiver is an elongated element with a longitudinal axis in the North-South direction. At least one first heat sensor is provided on the East side of the receiver, and at least one second heat sensor is provided on the West side of the receiver. A control unit is adapted to compare the measurements of the first and second heat sensors and send a signal to a motor, which adjusts the inclination angle of the collector surface East or West in the direction of the heat sensor registering the lower temperature. Commercially available non contact heat sensors may be used for this purpose, generally located at one end of the collector, when a parabolic trough is used.

The system whereby two heat sensors proximate the receiver are used to control the inclination angle of the collector surface is not operational at all times. The control system provides for taking the focus system into service and out of service. At the beginning of the day, for example, an optical sensor determines whether sufficient sunlight is available for operation, and the control unit sends a signal to the motor to begin the focusing operation, relying on the heat sensors as described above. At night, again responsive to a reading from an optical sensor, the control unit sends a signal to return the collector surface to a parked position, which may be a full East-facing position, but is more preferably a horizontal position, with the reflector surfacing facing straight up at the 12 o'clock position. The control system is also provided with an override when an error condition is detected, as described below.

A plurality of substantially identical solar collector units may be connected in series, so that the heat transfer fluid exiting a first unit becomes the heat transfer fluid input to a second unit. In this case, it may be preferable to have a single motor controlling the inclination angle of two adjacent units.

According to the invention, the tracking control system is provided with error condition detection and management which may also override the system for focusing solar radiation on the receiver. To provide error condition detection, a fluid temperature sensor is provided to measure the temperature of the heat transfer fluid carried in the receiver. The type of fluid temperature sensor used is not particularly limited and any conveniently sized thermocouple or infra red (IR) sensor may be used. The fluid temperature sensor is placed to measure the temperature of the heat transfer fluid exiting the apparatus (T1).

A predetermined error condition value (Te) is established to determine if the apparatus is overheating. What constitutes overheating varies depending on the application, but for water used to heat a laundry, for example, the desired heat transfer fluid (water) temperature exiting the collector may be in a range of 90° F. to 100° F. and Te may be set in a range from about 105° F. to 110° F. Thus, the error condition value Te exceeds the top end of the desired temperature range by a predetermined amount, such as 5%, 10%, 15% or 20% of the maximum desired value for T1. When T1 exceeds Te, the control system causes the motor to defocus the reflective surface. The collector surface is defocused by moving it to the East, as shown in FIGS. 2A and 2B. In an initial state, depicted in FIG. 2A, solar rays 70 are focused on receiver 60 as a result of the focusing effect of the reflective parabolic surface 20. When T1 is greater than Te, the receiver is shifted to the East and the state depicted in 2B is achieved. Although the mirror may be defocused by shifting either to the East or West, it is preferred that the reflective surface is shifted to the East, so that the progress of the sun toward the West does not cause the sun's rays to be refocused on the receiver at the later position. Generally, the inclination angle a is shifted at least about 5 degrees, preferably more than 10 degrees, and most preferably about 15 degrees. As seen in FIG. 2B, the rays are not focused on the receiver as a result of the shift, but on a point 90, and the temperature of the heat transfer fluid in the receiver drops. After a period of time, if T1 falls sufficiently below Te to a second set point for a sufficient period of time, the focusing control can reset, so that the control unit again obtains a comparison of the heat sensors on the East and West of the receiver to refocus the solar radiation on the receiver. Alternatively, the collector may simply be taken out of service, returned to the full East-facing position until the problem can be investigated and rectified. It is preferable to avoid cycling, whereby T1 repeatedly exceeds Te within a few minutes after being put back on line. Taking the collector out of service may be accompanied by an alarm generated by the control unit, which alerts the operator to an error condition after T1 exceeds Te for two, three or other predetermined number of cycles.

The temperature sensor of the defocus capability is advantageously located at the outflow of the heat transfer fluid from the collector unit. When a plurality of collector units are provided in series, a single defocus capability located between adjacent units controls the inclination angle of both units.

As used herein, two solar collector units according to the invention arranged in series are “substantially” identical provided each unit has the same features, notwithstanding that there may be some differences in construction between the two units. Of course, two units connected in series with a single motor between them controlling the common inclination angle cannot be identical, but they may be substantially identical as that phrase is understood herein. A surface is “substantially” flat when its overall dimensions are flat, notwithstanding some variation on the surface. As used herein, when a numerical value requiring measurement is modified by the term “about,” that value is understood to encompass a margin of error normally associated with taking that particular measurement.

The foregoing description of the preferred embodiments is not to be deemed limiting of the invention, which is defined by the following claims.

What is claimed is:

1. A solar collector apparatus, comprising: (1) a passive solar collector unit having a reflective collector surface disposed at an inclination angle; (2) an active solar collector unit having an active collector surface disposed at the same inclination angle and moving in unison with the reflective collector surface; and (3) a tracking control system controlling the inclination angle of the reflective collector surface and the active collector surface.

2. The solar collector apparatus according to claim 1, wherein the tracking control system comprises: a receiver element located in a focal area of the reflective collector surface carrying a heat transfer fluid; a plurality of heat sensors proximate the receiver element; a motor; and a control unit, wherein the control unit is adapted to obtain a comparison of measurements obtained from each of the plurality of heat sensors and to provide a signal to the motor to adjust the inclination angle on the basis of the comparison.

3. The solar collector apparatus according to claim 1, wherein
the passive solar collector unit comprises: (a) a reflective collector surface in the shape of a parabolic trough having a straight longitudinal side with an edge, and (b) a receiver carrying heat transfer fluid located on the focal line of the parabolic trough; and wherein
the active solar collector unit comprises (a) at least one substantially flat photovoltaic panel extending from the edge of the reflective collector surface.

4. The solar collector apparatus according to claim 2, wherein the solar collector apparatus is a first solar collector apparatus, and heat transfer fluid exiting the first solar collector apparatus provides a heat transfer fluid input to an attached substantially identical second solar collector apparatus.

5. The solar collector apparatus according to claim 4, wherein a single motor adjusts the inclination angle of the first solar collector apparatus and the inclination angle of the second solar collector apparatus at the same time.

6. The solar collector apparatus according to claim 1, comprising: (1) a passive solar collector unit having a focusing reflector surface and an associated receiver element, the receiver element carrying heat transfer fluid in a focal area of the reflector; (2) a motor for adjusting an inclination angle of the focusing reflector surface; (3) a plurality of heat sensors positioned proximate the receiver element and operatively connected to a control unit for controlling the motor for adjusting the inclination angle of the focusing reflector surface, whereby solar radiation is focused on the receiver element following the apparent movement of the sun in the sky; at (4) least one flat photovoltaic panel attached to the passive solar collector unit so that the surface of the flat photovoltaic panel moves with the inclination angle of the reflector such that a line normal to the surface of the photovoltaic panel is parallel to the axis of symmetry of the focusing reflector surface.

7. The solar collector apparatus according to claim 1, wherein the tracking control system comprises: an elongated receiver with a longitudinal axis in the North-South direction carrying a heat transfer fluid; at least one first heat sensor proximate the receiver on the East side of the receiver; at least one second heat sensor proximate the receiver on the West side of the receiver; and a control unit adapted to adjust the inclination angle of the collector surface to the East or West responsive to a comparison of measurements from the first and second heat sensors.

8. The solar collector apparatus according to claim 1, wherein the reflective collector surface comprises a curved foam support on which a reflective material is adhered, the foam support having a plurality of alignment rods extending along its length, and wherein the curved surface is open to the elements.

9. The solar collector apparatus according to claim 8, wherein the foam support is expanded polystyrene having a density in a range of about 0.9 ft/lb³ to about 2.2 lb/ft³.

10. The solar collector apparatus according to claim 2, wherein the reflective collector surface comprises a curved foam support placed in a cradle having a transparent cover.

11. A tracking control system for a solar collector, comprising: (1) a focusing collector surface; (2) an associated receiver carrying heat transfer fluid in a focal area of the collector surface; (3) a plurality of heat sensors positioned proximate the receiver; (4) a fluid temperature sensor adapted to measure the temperature of heat transfer fluid exiting the collector unit; (5) a motor operatively connected to the collector surface for adjusting the inclination angle of the collector surface; (6) a comparator comparing the fluid temperature of heat transfer fluid exiting the passive unit with a predetermined error condition value; and (7) a control unit operatively connected to the comparator, the plurality of heat sensors and the motor, and adapted to defocus the collector surface by moving the inclination angle to the East when the heat transfer fluid exiting the unit is above the predetermined error condition value.

12. The tracking control system of claim 11, wherein the heat transfer fluid exiting the unit provides a heat transfer fluid input to an attached substantially identical second solar collector apparatus, and the motor moves the inclination angle of both collectors at the same time.

13. The tracking control system according to claim 11, further comprising: an elongated receiver with a longitudinal axis in the North-South direction; at least one first heat sensor proximate the receiver on the East side of the receiver; at least one second heat sensor proximate the receiver on the West side of the receiver; and a control unit adapted to adjust the inclination angle of the collector surface to the East or West responsive to a comparison of measurements obtained from the first and second heat sensors.

14. A method for managing an error condition in a solar collector apparatus, having a focusing collector surface; an associated receiver carrying heat transfer fluid in a focal area of the collector surface; a plurality of heat sensors positioned proximate the receiver; a fluid temperature sensor adapted to measure the temperature of heat transfer fluid exiting the collector unit, a motor for adjusting an inclination angle of the collector surface; and a control unit; comprising the steps of:
(a) performing a comparison of measurements from the plurality of heat sensors;
(b) adjusting the inclination angle of the collector surface to focus solar radiation incident on the collector surface onto the receiver responsive to the comparison performed in step (a);
(c) measuring the temperature of heat transfer fluid exiting the apparatus;
(d) performing a comparison of the measurement obtained in step (c) with a predetermined error condition value; and
(e) adjusting the inclination angle at least 10 degrees to the East when the measurement obtained in step (c) is greater than the predetermined error condition value.

15. The method according to claim 14, further comprising the step of:
(f) performing steps (a) and (b) when the measurement obtained in step (c) is a predetermined amount less than a set point less than the predetermined error condition value.

16. The method according to claim 14 wherein the control unit signals an alarm when T1 exceeds Te for more than a predetermined number of cycles.

17. The method according to claim 14, wherein the control unit returns the solar collector apparatus to the full East-facing position when T1 exceeds Te for more than a predetermined number of cycles.

18. The method according to claim 14, wherein the motor controls the inclination angle of two adjacent solar collector units arranged in series so that the heat transfer fluid exiting a first collector unit is input to a second adjacent collector unit.
